(19) United States
(12) Patent Application Publication
(10) Pub. No.: US 2004/0066220 A1
(43) Pub. Date: Apr. 8, 2004

(54) High-speed high-current programmable charge-pump circuit

(76) Inventor: Chun-Chieh Chen, Taipei (TW)

Correspondence Address: RABIN & Berdo, PC, 1101 14TH STREET, NW, SUITE 500, WASHINGTON, DC, 20005, US

(21) Appl. No.: 10/263,085

(22) Filed: Oct. 3, 2002

(51) Int. Cl. H03L 7/06

(52) U.S. Cl. 327/157

(57) ABSTRACT

A high-speed high-current charge-pump circuit capable of outputting a programmable current range. The charge-pump circuit includes first and second current mirror circuits. The first and the second current mirror circuits produce a first output current from a first supply current and a second output current from a second supply current, respectively, and sources/sinks the first and the second output currents to and from an output node. Also, the charge-pump circuit includes first and second current steering means. The first current steering means directs the first supply current to the first current mirror circuit in response to a first pair of differential signals. On the other hand, the second current steering means directs the second supply current to the second current mirror circuit in response to a second pair of differential signals.

### BACKGROUND OF THE INVENTION

1. Field of the Invention

The invention relates to a charge-pump circuit. More particularly, the invention relates to a high-speed high-current charge-pump circuit for use in an offset phase-locked loop (PLL).

2. Description of the Related Art

In recent years, the fast growth of cellular communications systems has motivated an increasing demand for high performance integrated radio frequency (RF) components. One of the most important building blocks of these systems is the local oscillator (LO). The need for a well defined and highly stable signal for the local oscillator makes necessary the use of phase locked loop (PLL) techniques to satisfy the stringent requirements of wireless standards. Among the different PLL topologies, the offset PLL is used in most current GSM handsets as it provides better power efficiency, cost and performance by reducing the filter numbers in the transmission path. The offset PLL is a PLL with a down-conversion mixer in the feedback path and is used in the transmit (Tx) path as a frequency converter. It has a tracking bandpass filter characteristic employed in such a way that the offset PLL can suppress the noise in the GSM receiving band (Tx noise) without a duplexer. This technique offers a cost-effective way to suppress spurious noise in a RF transmitter.

A fundamental building block of the offset PLL is the charge-pump circuit, since this circuit controls the VCO frequency. In the integrated circuit design, the charge-pump circuit must be capable of offering a high charge-pump current to fulfill the high switching speed requirement of the RF transmitter. FIG. 1 illustrates a conventional charge-pump circuit that can be found in G. Irvine, et al., “An Up-Conversion Loop Transmitter IC for Digital Mobile Telephones”, IEEE Int. Solid-States Circuits Conf., San Francisco, pp. 364-365, February 1998. The circuit of FIG. 1 is fast enough to follow modulation, but there always exist two currents flowing through resistors R1 and R2 respectively. This results in unavoidable power consumption. Furthermore, it requires an extra operational amplifier to keep the collector voltage of Q5 constant, thus resulting in an increase in production cost. Accordingly, there is a need for a charge-pump circuit that addresses the disadvantages of the prior art. In addition, manufacturing process variations may prevent the PLL loop gain from constant. It is also desired to provide a charge-pump circuit supporting programmable output to compensate for such variations.

### SUMMARY OF THE INVENTION

It is an object of the present invention to provide a charge-pump circuit for use in a RF transmitter IC which features high switching speed, high output current and low power consumption.

It is another object of the present invention to provide a charge-pump circuit capable of outputting a programmable current range.

According to one aspect of the invention, a high-speed high-current charge-pump circuit includes a first current mirror circuit, a second current mirror circuit, a first programmable current source and a second programmable current source. The first current mirror circuit produces a first output current from a first supply current and sources the first output current to an output node. The second current mirror circuit produces a second output current from a second supply current and sinks the second output current from the output node. The first and the second programmable current sources are configured to vary the magnitudes of the first and the second supply currents under control of an adjustment signal, respectively. Additionally, the charge-pump circuit includes a first current steering means for directing the first supply current to a first branch or the first current mirror circuit in response to a first pair of differential signals. The charge-pump circuit also contains a second current steering means for directing the second supply current to a second branch or the second current mirror circuit in response to a second pair of differential signals.

Preferably, the first current steering means is composed of first and second transistors to receive the first pair of differential signals. The first transistor is coupled between the first branch and the first programmable current source, and the second transistor is coupled between the first current mirror circuit and the first programmable current source. Likewise, the second current steering means is composed of third and fourth transistors to receive the second pair of differential signals. The third transistor is coupled between the second branch and the second programmable current source, and the fourth transistor is coupled between the second current mirror circuit and the second programmable current source.

### BRIEF DESCRIPTION OF THE DRAWINGS

The present invention will be described by way of exemplary embodiments, but not limitations, illustrated in the accompanying drawings in which like references denote similar elements, and in which:

FIG. 1 is a schematic diagram illustrating a charge-pump circuit in accordance with the prior art;

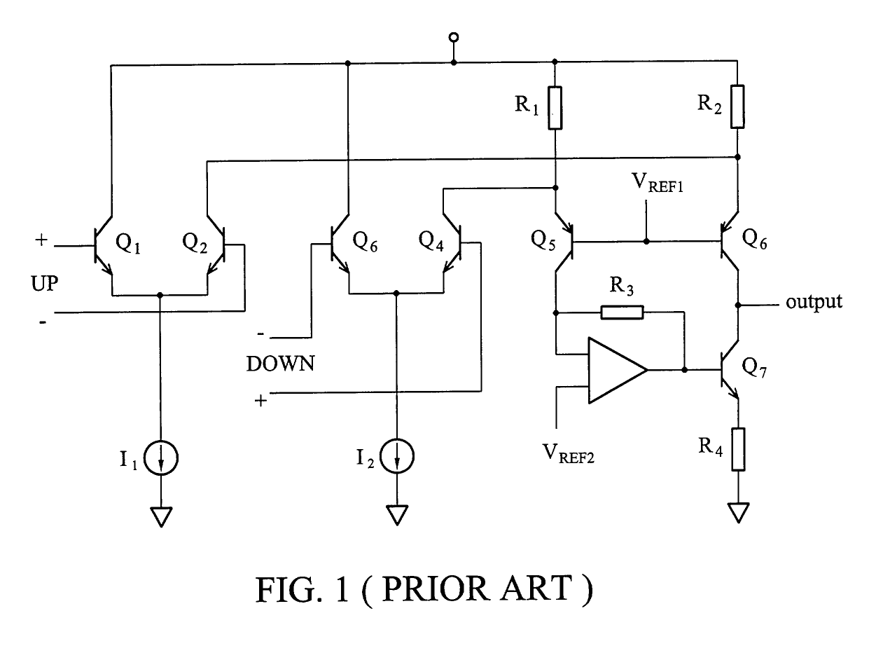

FIG. 2 is a block diagram illustrating a charge-pump circuit in accordance with the present invention; and

FIG. 3 is a schematic diagram illustrating the charge-pump circuit of FIG. 2.

### DETAILED DESCRIPTION OF THE INVENTION

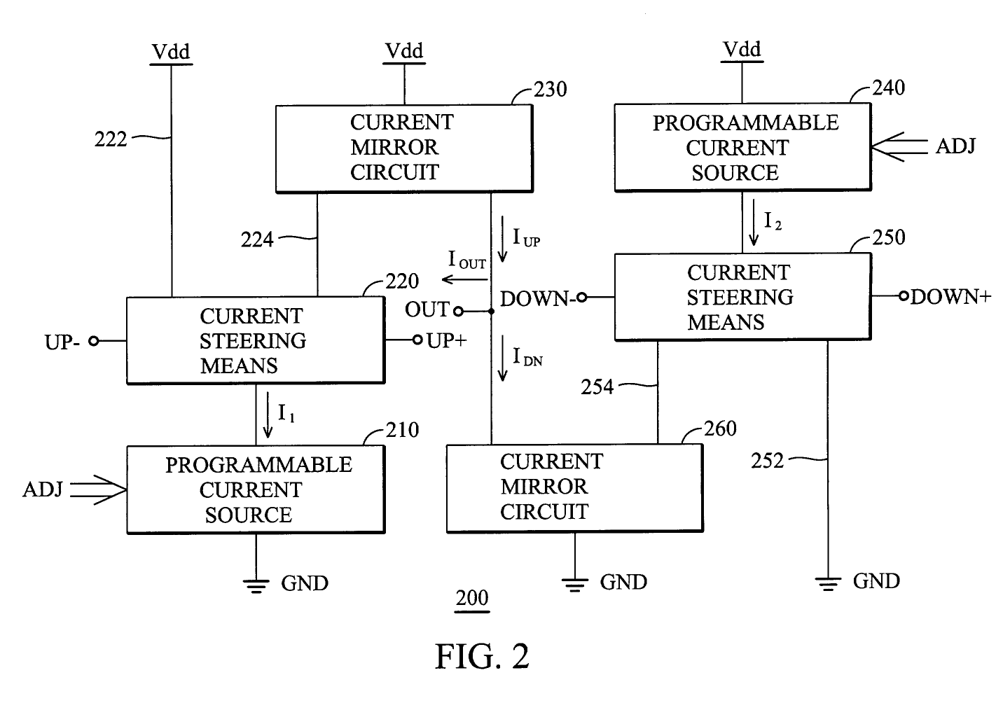

With reference to FIG. 2, a block diagram of a charge-pump circuit 200 is shown in accordance with the invention. The charge-pump circuit 200 is made up of two programmable current sources, two current mirror circuits and two current steering means. The circuit 200 is powered by a power supply Vdd as a high-potential power supply and a ground GND. The programmable current source 210 supplies a current I₁ to the current steering means 220 and the programmable current source 240 supplies a current I₂ to the current steering means 250. Under control of an adjustment signal ADJ, the programmable current sources 210 and 240 are programmed to vary the magnitudes of the supply currents I₁ and I₂, respectively. As depicted, a pair of differential signals UP+ and UP− are applied to the current steering means 220 and another pair of differential signals DOWN+ and DOWN− are applied to the current steering means 250. The current steering means 220 directs the current I₁ to a branch 222 connected to the power supply Vdd or a branch 224 connected to the current mirror circuit 230 in response to the differential signal pair UP+ and UP−. On the other hand, the current steering means 250 directs the current I₂ to a branch 252 connected to the ground GND or a branch 254 connected to the current mirror circuit 260 in response to the differential signal pair DOWN+ and DOWN−. The current mirror circuit 230 is used to produce a pump-up current Iᵤₚ from the current I₁ and sources the pump-up current Iᵤₚ to an output node OUT. The current mirror circuit 260 is used to produce a pump-down current I_{DN} from the current I₂ and lowers the pump-down current I_{DN} from the node OUT.

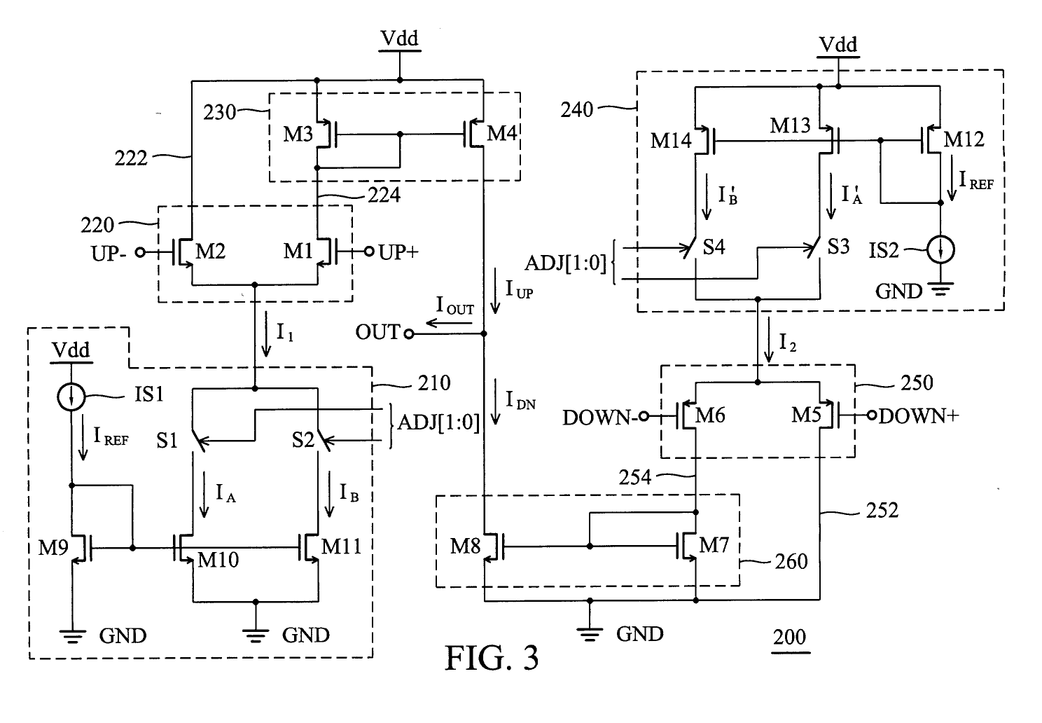

With reference to FIG. 3, a detailed schematic diagram of the charge-pump circuit 200 is shown in accordance with a preferred embodiment of the invention. Note that each transistor described herein is either a P-type or N-type MOS transistor having a gate, a drain and a source. Since a MOS transistor is typically a symmetrical device, the true designation of “source” and “drain” is only possible once a voltage is impressed on the terminals. The designations of source and drain herein should be interpreted, therefore, in the broadest sense. It should be understood to those skilled in the art that other transistor technologies are contemplated to implement the transistors illustrated in FIG. 3 by the principles of the invention. As depicted, the current steering means 220 is constructed of transistors M1 and M2 which form the differential-pair configuration. The transistors M1 and M2 have their sources connected together and fed by the current source 210. The transistor M2 has its drain connected to the power supply Vdd through the branch 222. The transistor M1 has its drain connected to the current mirror circuit 230 through the branch 224. Additionally, gates of the transistors M1 and M2 receive the differential signal pair UP+ and UP− respectively. The differential-pair configuration is adopted due to its fast switching characteristics. Notably, the current steering means 220 is fed by the differential signal pair with the signals UP+ and UP− applied in a complementary fashion.

The current steering means 250, on the other hand, includes transistors M5 and M6 forming the differential-pair configuration. The transistors M5 and M6 have their sources connected together and fed by the current source 240. The transistor M5 has its drain connected to the ground GND through the branch 252. The transistor M6 has its drain connected to the current mirror circuit 260 through the branch 254. Additionally, gates of the transistors M5 and M6 receive the differential signal pair DOWN+ and DOWN− respectively. Likewise, the current steering means 250 is fed by the differential signal pair with the signals DOWN+ and DOWN− applied in a complementary fashion.

The current mirror circuit 230 includes transistors M3 and M4 with their gates connected together. Both sources of the transistors M3 and M4 are connected to the power supply Vdd. The transistor M4 has its drain connected to the node OUT. Conversely, the transistor M3 has its drain connected to the branch 224. In addition, the transistor M3 is connected as a diode by shorting its drain to its gate. With the current mirror circuit 230, a current is generated in the branch 224 and is then reproduced at the output node OUT for the purpose of charging a loop filter (not shown) following the charge-pump circuit 200. In a similar fashion, transistors M7 and M8 form the current mirror circuit 260. The transistors M7 and M8 have their gates connected together and their sources connected to the ground GND. The transistor M8 has its drain connected to the node OUT. The transistor M7 is also connected as a diode by shorting its drain to its gate, and the drain of the transistor M7 is further connected to the branch 254. With the current mirror circuit 260, a current is generated in the branch 254 and is then reproduced at the output node OUT for the purpose of discharging the loop filter.

When the signal UP+ is at a logic high level and the signal UP− is at a logic low level, the transistor M1 is turned on and the transistor M2 is turned off. Thus, the current I₁ is steered through M1 to the transistor M3 and is mirrored to the transistor M4 as the pump-up current Iᵤₚ. Conversely, the transistor M1 is turned off and the transistor M2 is turned on when the signal UP+ is at the logic low level and the signal UP− is at the logic high level. The current I₁ is steered through M2 to the branch 222, which allows the current Iᵤₚ at the node OUT to fall to zero quickly. On the other hand, when the signal DOWN+ is at the logic high level and the signal DOWN− is at the logic low level, the transistor M6 is turned on and the transistor M5 is turned off. In this way, the current I₂ is steered through M6 to the transistor M7 and is mirrored to the transistor M8 as the pump-down current I_{DN}. When the signal DOWN+ is at the logic low level and the signal DOWN− is at the logic high level, the transistor M6 is turned off and the transistor M5 is turned on. The current I₂ is steered through M5 to the branch 252, which allows the current I_{DN} at the node OUT to fall to zero quickly.

The output current I_{OUT} of the charge-pump circuit 200 is the sum of the current Iᵤₚ and the current I_{DN} (according to the flow directions shown in FIG. 2) at the node OUT. Since the PLL loop gain varies directly with the charge-pump current I_{OUT}, it can be offset by adjusting the charge-pump current I_{OUT}. The use of the programmable current sources 210 and 240 allows the charge-pump circuit 200 to support a variable charge-pump current range. As an example of the implementation, one embodiment for the programmable current sources 210 and 240 is illustrated in FIG. 3 as well. For instance, switches S1 and S2, transistors M9 through M11 and a constant current source IS1 form the programmable current source 210. Likewise, the programmable current source 240 is made up of switches S3 and S4, transistors M12 through M14 and a constant current source IS2. Each of the constant current sources IS1 and IS2 supplies the same current magnitude I_{REF}. The diode-connected transistor M9 forms a current mirror with the transistor M10. Thus the transistor M10 provides a current I_{A} equal to I_{REF}. The transistor M11 connected in parallel with the transistor M10 forms a mirror with the transistor M9. To generate a current whose magnitude is a multiple of I_{REF}, the transistor M11 is designed to have a geometry ratio equal to the desired multiple. In one embodiment, the transistor M11 has twice the ratio of the transistor M9, thus supplying a current I_{B}=2I_{REF}. The switches S1 and S2 are respectively connected in series with the transistors M10 and M11. In this way, the supply current I₁ is a resultant current of the currents I_{A} and I_{B} depending on the adjustment signal ADJ. As illustrated in FIG. 3, the programmable current source 240 is implemented with a similar configuration. Therefore, the transistor M13 supplies a current I_{A}′ equal to I_{REF}, and the transistor M14 supplies a current I_{B}′ equal to 2I_{REF}. The supply current I₂ is a resultant current of the currents I_{A}′ and I_{B}′ depending on the adjustment signal ADJ.

The switches S1, S2 in the current source 210 and the switches S3, S4 in the current source 240 are programmed on or off based on the same signal, i.e., the adjustment signal ADJ. Alternatively, the switches in the current source 210 and 240 are respectively controlled by different signals. In one embodiment, the same adjustment signal ADJ[1:0] is applied to these switches. For example, the signal ADJ[1:0] with a value of “01” (in terms of binary notation) turns on the switches S1 and S3 but turns off the switches S2 and S4. The current sources 210 and 240 supply the currents I₁ and I₂ equal to I_{REF}, respectively. If the signal ADJ[1:0] is “10”, the switches S1 and S3 are turned off but the switches S2 and S4 are turned on. The current sources 210 and 240 supply the currents I₁ and I₂ equal to 2I_{REF}, respectively. Furthermore, the switches S1 through S4 are turned on together if the signal ADJ[1:0] is “11”, whereby the current sources 210 and 240 respectively provide the resultant currents I₁ and I₂ equal to 3I_{REF} (i.e. I_{REF}+2I_{REF}). Accordingly, the charge-pump circuit 200 is capable of generating a programmable charge-pump current range.

While the invention has been described by way of example and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A charge-pump circuit having an output node comprising:
a first current mirror circuit for producing a first output current from a first supply current and sourcing the first output current to the output node;
a second current mirror circuit for producing a second output current from a second supply current and sinking the second output current from the output node;
a first programmable current source configured to vary the magnitude of the first supply current controlled by an adjustment signal;
a second programmable current source configured to vary the magnitude of the second supply current controlled by the adjustment signal;
a first current steering means for directing the first supply current to a first branch or the first current mirror circuit in response to a first pair of differential signals, comprising first and second transistors to receive the first pair of differential signals, wherein the first transistor is coupled between the first branch and the first programmable current source, and the second transistor is coupled between the first current mirror circuit and the first programmable current source; and
a second current steering means for directing the second supply current to a second branch or the second current mirror circuit in response to a second pair of differential signals, comprising third and fourth transistors to receive a second pair of differential signals, wherein the third transistor is coupled between the second branch and the second programmable current source, and the fourth transistor is coupled between the second current mirror circuit and the second programmable current source.

2. The charge-pump circuit as recited in claim 1 wherein the first transistor is turned off and the second transistor is turned on to direct the first supply current to the first current mirror when the first pair of differential signals are received at a predetermined current-source state.

3. The charge-pump circuit as recited in claim 1 wherein the third transistor is turned off and the fourth transistor is turned on to direct the second supply current to the second current mirror when the second pair of differential signals are received at a predetermined current-sink state.

4. The charge-pump circuit as recited in claim 1 wherein the first programmable current source comprises a plurality of switches controlled by the adjustment signal to vary the magnitude of the first supply current.

5. The charge-pump circuit as recited in claim 1 wherein the second programmable current source comprises a plurality of switches controlled by the adjustment signal to vary the magnitude of the second supply current.

6. The charge-pump circuit as recited in claim 1 wherein the first current steering means is fed by the first differential signal pair with the first differential signal pair applied in a complementary fashion, and the second current steering means is fed by the second differential signal pair with the second differential signal pair applied in the complementary fashion.

7. A charge-pump circuit having an output node comprising:
a first current mirror circuit for producing a first output current from a first supply current and sourcing the first output current to the output node;
a second current mirror circuit for producing a second output current from a second supply current and sinking the second output current from the output node;
a first programmable current source configured to vary the magnitude of the first supply current controlled by an adjustment signal;
a second programmable current source configured to vary the magnitude of the second supply current controlled by the adjustment signal;
a first current steering means coupled between a first branch, the first current mirror circuit and the first programmable current source, for directing the first supply current to the first branch or the first current mirror circuit in response to a first pair of differential signals; and
a second current steering means coupled between a second branch, the second current mirror circuit and the second programmable current source, for directing the second supply current to the second branch or the second current mirror circuit in response to a second pair of differential signals.

8. The charge-pump circuit as recited in claim 7 wherein the first current steering means comprises first and second transistors to receive the first pair of differential signals, and the second current steering means comprises third and fourth transistors to receive the second pair of differential signals.

9. The charge-pump circuit as recited in claim 8 wherein the first transistor is coupled between the first branch and the first programmable current source, and the second transistor is coupled between the first current mirror circuit and the first programmable current source.

10. The charge-pump circuit as recited in claim 9 wherein the first transistor is turned off and the second transistor is turned on to direct the first supply current to the first current mirror when the first pair of differential signals are received at a predetermined current-source state.

11. The charge-pump circuit as recited in claim 8 wherein the third transistor is coupled between the second branch and the second programmable current source, and the fourth transistor is coupled between the second current mirror circuit and the second programmable current source.

12. The charge-pump circuit as recited in claim 11 wherein the third transistor is turned off and the fourth transistor is turned on to direct the second supply current to the second current mirror when the second pair of differential signals are received in a predetermined current-sink state.

13. The charge-pump circuit as recited in claim 7 wherein the first programmable current source comprises a plurality of switches controlled by the adjustment signal to vary the magnitude of the first supply current.

14. The charge-pump circuit as recited in claim 7 wherein the second programmable current source comprises a plurality of switches controlled by the adjustment signal to vary the magnitude of the second supply current.

15. A charge-pump circuit having an output node comprising:
a first current mirror circuit for producing a first output current from a first supply current and sourcing the first output current to the output node;
a second current mirror circuit for producing a second output current from a second supply current and sinking the second output current from the output node;
a first current source for supplying the first supply current; and
a second current source for supplying the second supply current.

16. The charge-pump circuit as recited in claim 15 further comprising:
a first current steering means for directing the first supply current to the first current mirror in response to a first pair of differential signals; and
a second current steering means for directing the second supply current to the second current mirror in response to a second pair of differential signals.

17. The charge-pump circuit as recited in claim 15 wherein the first and the second current sources are programmed to vary the magnitudes of the first and the second supply currents controlled by an adjustment signal, respectively.

18. The charge-pump circuit as recited in claim 17 wherein the first current source comprises a plurality of switches controlled by the adjustment signal to vary the magnitude of the first supply current.

19. The charge-pump circuit as recited in claim 17 wherein the second current source comprises a plurality of switches controlled by the adjustment signal to vary the magnitude of the second supply current.

20. The charge-pump circuit as recited in claim 16 wherein the first current steering means is enabled to direct the first supply current to the first current mirror when the first pair of differential signals are received in a predetermined current-source state, and the second current steering means is enabled to direct the second supply current to the second current mirror when the second pair of differential signals are received in a predetermined current-sink state.
